(19) United States
(12) Patent Application Publication
(10) Pub. No.: US 2026/0068573 A1
(43) Pub. Date: Mar. 5, 2026

(54) METHOD FOR GRINDING A WAFER

(71) Applicant: STATS ChipPAC Pte. Ltd., Singapore (SG)

(72) Inventors: YiJing Eric CHONG, Singapore (SG); Rowena ZARATE, Singapore (SG); Marites ROQUE, Singapore (SG); PeiEe Linda CHUA, Singapore (SG)

(21) Appl. No.: 19/318,399

(22) Filed: Sep. 4, 2025

(30) Foreign Application Priority Data
Sep. 5, 2024 (CN) 202411243115.3

(51) Int. Cl. H01L 21/304; B24B 7/22

(52) U.S. Cl. CPC H10P 52/00; B24B 7/228

(57) ABSTRACT

A method for grinding a wafer is provided. The method comprises: providing a wafer having a back side and a front side opposite to the back side, wherein the wafer further comprises a central zone for accommodating semiconductor units and a peripheral zone surrounding the central zone; forming a trench within the peripheral zone and extending along substantially an entire circumference of the peripheral zone, wherein the trench is exposed from the front side of the wafer; filling the trench with a filler to form a spacer ring within the peripheral zone, wherein the spacer ring isolates the central zone from an edge of the wafer; attaching the wafer onto a platform at the front side of the wafer; and grinding the wafer from the back side of the wafer.

### TECHNICAL FIELD

The present application generally relates to semiconductor technology, and more particularly, to a method for grinding a wafer.

### BACKGROUND OF THE INVENTION

The semiconductor industry is constantly faced with complex integration challenges as consumers want their electronics to be smaller, faster and higher performance with more and more functionalities packed into a single device. Typically, multiple electronic components are fabricated within a wafer. Then a sawing process may be conducted to the wafer to singulate the wafer into a plurality of dice. The dice may be encapsulated with other electronic modules to form an electronic package device.

Before the wafer undergoes the sawing process, a grinding process may be implemented from a back side of the wafer to reduce a thickness of the wafer. However, cracks may occur on an edge of the wafer due to an external stress applied to the wafer during the grinding process. The cracks may easily propagate into a central region of the wafer where the electronic components are formed, thereby resulting in severe wafer damage and a reduced yield.

Therefore, a need exists for a method for grinding a wafer.

### SUMMARY OF THE INVENTION

An objective of the present application is to provide a method for grinding a wafer which reduces wafer damage and improves yield.

According to an aspect of the present application, a method for grinding a wafer is provided. The method comprises: providing a wafer having a back side and a front side opposite to the back side, wherein the wafer further comprises a central zone for accommodating semiconductor units and a peripheral zone surrounding the central zone; forming a trench within the peripheral zone and extending along substantially an entire circumference of the peripheral zone, wherein the trench is exposed from the front side of the wafer; filling the trench with a filler to form a spacer ring within the peripheral zone, wherein the spacer ring isolates the central zone from an edge of the wafer; attaching the wafer onto a platform at the front side of the wafer; and grinding the wafer from the back side of the wafer.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1I illustrate various steps of a method for grinding a wafer according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, in a semiconductor fabrication process, multiple electronic components may be fabricated within a wafer. The electronic components may be formed within a central zone of the wafer. Typically, a peripheral zone surrounding the central zone may be more vulnerable to an external stress due to a smaller thickness, larger exposure to a processing environment or less support from adjacent structures, for example. Thus, when a grinding process is conducted from a back side of the wafer, cracks may occur on an edge of the wafer. The cracks may easily propagate through the peripheral zone and then branch out into the central zone of the wafer. Thereby, the cracks may adversely affect reliability of the electronic components, and result in severe wafer damage and a reduced yield.

To address this issue, a new method for grinding a wafer is provided. The new method includes forming a spacer ring within a peripheral zone of the wafer. The spacer ring extends along substantially an entire circumference of the peripheral zone to isolate a central zone from an edge of the wafer. In this way, the spacer ring blocks cracks formed at the edge of the wafer from propagating into the central zone of the wafer, thereby reducing wafer damage and improves yield.

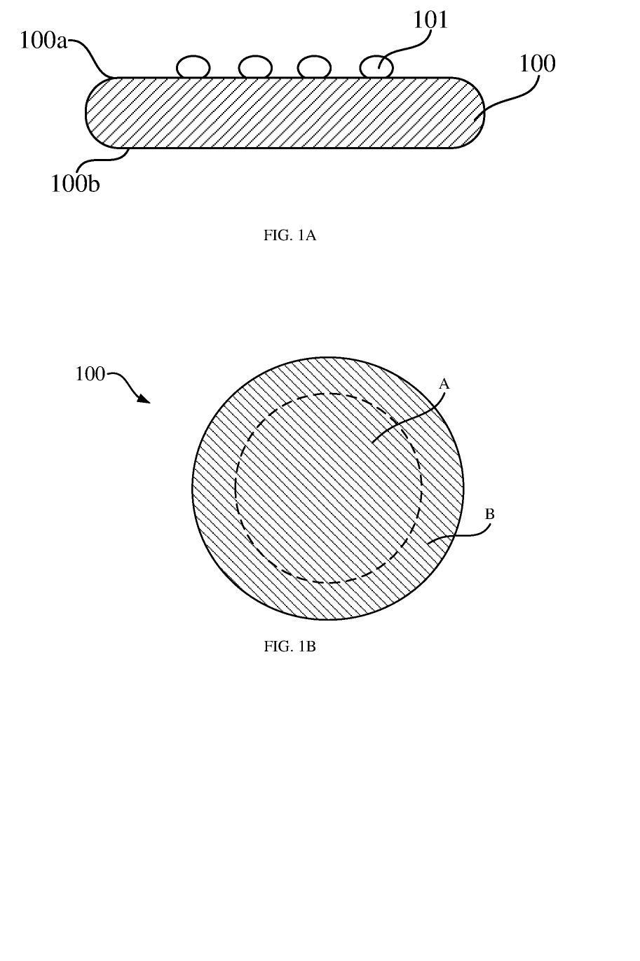

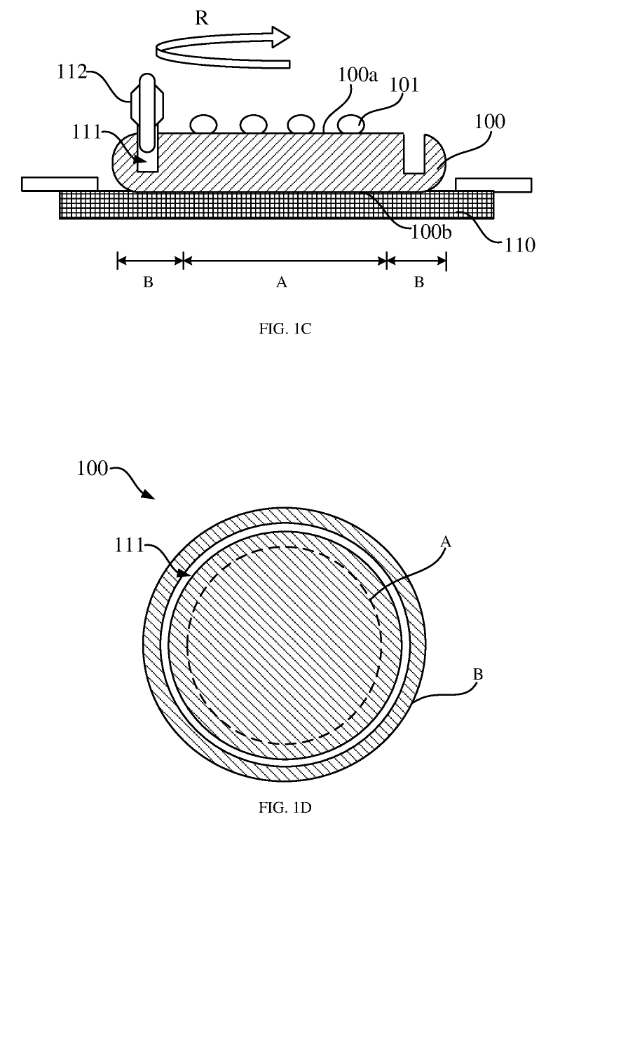

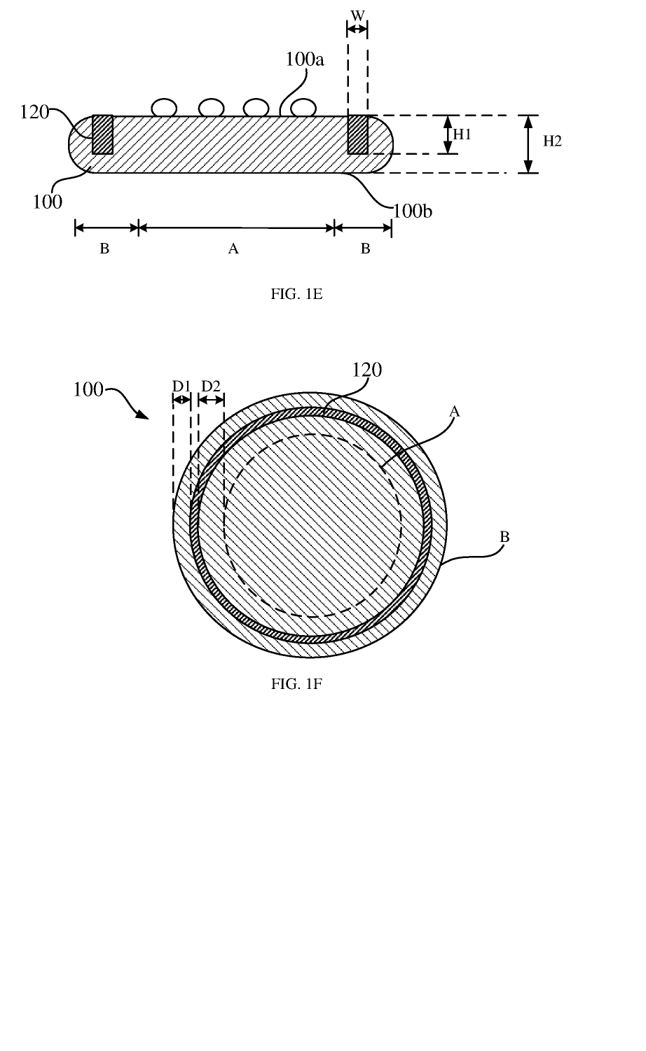

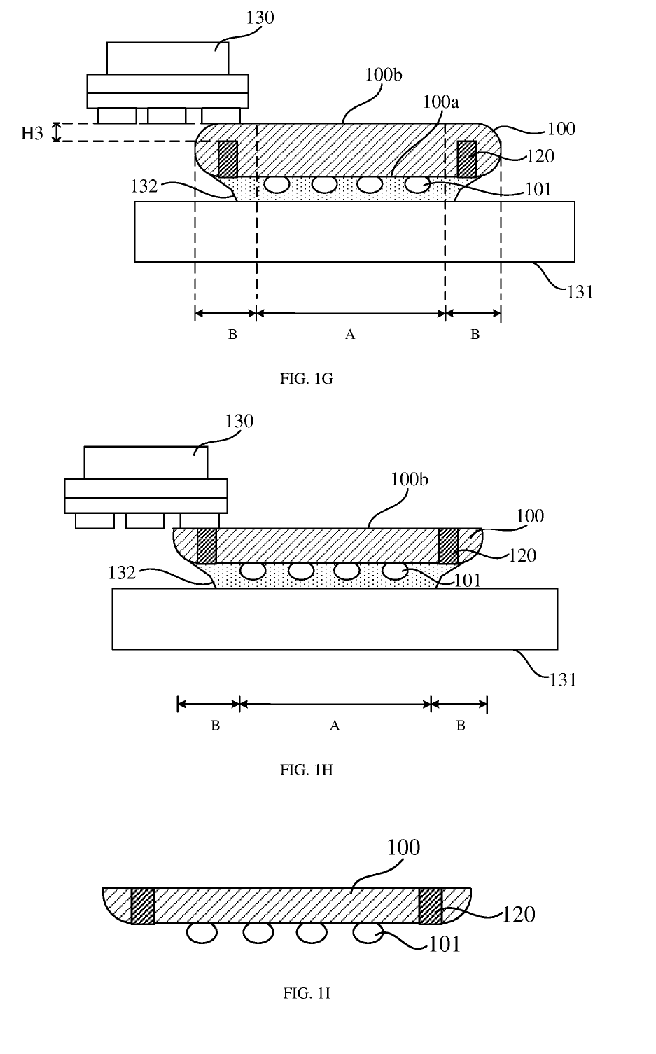

FIGS. 1A to 1I illustrate various steps of a method for grinding a wafer according to an embodiment of the present application.

FIGS. 1A and 1B illustrate a configuration of a wafer 100, where FIG. 1A illustrates a cross-sectional view of the wafer 100 and FIG. 1B illustrates a top view of the wafer 100 shown in FIG. 1A.

As shown in FIGS. 1A and 1B, the wafer 100 is provided with a front side 100a and a back side 100b opposite to the front side 100a. A plurality of semiconductor units are formed within the wafer 100 in front-end processes such as diffusion, lithography, implantation and deposition. The semiconductor units are arranged within a central zone A (as defined by dotted circle in FIG. 1B) of the wafer 100 which is farther away from an edge of the wafer 100, e.g., several millimeters or several centimeters or even farther from the edge of the wafer 100. The wafer 100 also includes a peripheral zone B surrounding the central zone A and being adjacent to the edge of the wafer 100, which is illustrated as a circular zone in FIG. 1B. A thickness of the wafer 100 may be constant in the central zone A, while a thickness may gradually decrease in the peripheral zone B when getting closer to the edge of the wafer 100. However, it should be noted that the boundary between the peripheral zone B and the central zone A may vary, for example, depending on whether and how the semiconductor units are formed within the wafer 100.

In some embodiments, a portion or all of the semiconductor units may be close to or exposed from the front side 100a of the wafer 100. For example, conductive structures of the semiconductor units may be exposed from the front side 100a for external connections. Meanwhile, a portion of a thickness of the wafer 100 close to the back side 100b may be free of electronic modules. Thus, a grinding process may be conducted subsequently to remove some or all of the portion of the wafer 100 from the back side 100b, thereby reducing the thickness of the wafer 100 without affecting the electrical functionality of the electronic modules within the wafer. Next, solder bumps 101 may be optionally formed on the front side 100a of the wafer 100, for example, on the conductive structures of the semiconductor units.

Next, as shown in FIGS. 1C and 1D, a trench 111 is formed within the peripheral zone B and exposed from the front side 100a of the wafer 100. Similar as FIGS. 1A and 1B, FIGS. 1C is a cross-sectional view of the wafer 100 and FIG. 1D is a top view of the wafer 100 shown in FIG. 1C. Before forming the trench 111, the back side 100b of the wafer 100 may be attached on a fixed trenching platform via a tape 110. In some embodiments, a drilling device 112 may be used to drill downwards from the front side 100a into an interior of the wafer 100 to form the trench 111. The drilling device 112 may be fixed on a rotating plate to turn around along an entire circumference of the wafer 100 (as illustrated as direction R in FIG. 1C) to form the trench 111. Thereby, the trench 111 is in the form of a circular ring and extends along substantially the entire circumference of the peripheral zone B. Alternatively, the drilling device 112 may be fixed, and the trenching platform may be rotating with the wafer 100 thereon to form the trench 111.

Other processes such as etching or ablation processes may be used to form the trench 111. In some embodiments, a mask layer with an opening passing therethrough may also be attached on the front side 100a of the wafer 100 to define a pattern of the trench 111 to be formed. Then an etching process may be conducted using the mask layer to remove a portion of the wafer 100 within the peripheral zone B to form the trench 111. It can also be appreciated that the trench 111 may be formed using laser ablation, milling, drilling, pinching or their combinations. Since the peripheral zone B may not include any semiconductor units, the formation of the trench 111 may not affect the electrical functionality of the wafer 100. In addition, the trench 111 area may be a certain distance away from the solder bumps 101 to avoid damages to the solder bumps 101.

As shown in FIG. 1D, the trench 111 is in the form of a circular ring. The trench 111 defines a position and a layout of a spacer ring to be formed within the trench 111. The details of the spacer ring will be elaborated below.

After the formation of the trench 111, the tape 110 may be removed to separate the wafer 100 from the trenching platform. In some embodiments, the tape 110 may be an ultraviolet (UV) sensitive tape. The UV sensitive tape may be hardened after UV irradiation with a certain wavelength range, as such the tape 110 can be easily removed from the wafer 100 and the trenching platform.

Next, as shown in FIGS. 1E and 1F, the trench 111 is filled with a filler, which forms a spacer ring 120 within the peripheral zone B. Similar as FIGS. 1A and 1B, FIGS. 1E is a cross-sectional view of the wafer 100 and FIG. 1F is a top view of the wafer 100 shown in FIG. 1E. In some embodiments, the filler may include epoxy. To be more specific, a filling material including a curing agent may be applied within the trench 111 and then be cured into the spacer ring 120. In some cases, the cured filler, i.e., the spacer ring 120 may have a hardness greater than that of the wafer 100 by choosing a suitable curing agent, such that the spacer ring 120 may improve endurance of the peripheral zone B. It can also be appreciated that the cured filler may have a hardness smaller than that of the wafer 100, such that the spacer ring 120 may serve as a buffer region which absorbs an impact when the peripheral zone B is exposed to an external stress.

In some embodiments, the spacer ring 120 has a top surface approximately aligned with the front surface of the wafer 100. In some other embodiments, a portion of the spacer ring 120 may slightly protrude from the front side 100a of the wafer 100, i.e., higher than a front side 100a of the wafer 100.

The spacer ring 120 can help to protect the wafer 100 in a subsequent grinding process. As shown in FIGS. 1E and 1F, the spacer ring 120 is disposed between the edge of the wafer 100 and the central zone A of the wafer 100. As such, when cracks occur on the edge of the wafer 100 during a subsequent grinding process, the spacer ring 120 may become a barrier between the edge and the central zone A of the wafer 100, thereby blocking the cracks from propagating into the central zone A. Since the spacer ring 120 extends along substantially an entire circumference of the peripheral zone B, the spacer ring 120 may provide all-around protection to the semiconductor units within the central zone A, thereby reducing wafer damage and improving yield after the subsequent grinding process.

As shown in FIG. 1E, a thickness H1 of the spacer ring 120 is determined by a depth of the trench 111 formed within the wafer 100. The thickness H1 of the spacer ring 120 may be larger than or the same as a predetermined thickness of the wafer 100 after being grinded. In some embodiments, the predetermined thickness of the wafer 100 after being grinded may be 50μm to 70μm. Accordingly, the thickness H1 of the spacer ring 120 may be 60μm to 90μm. In some embodiments, the thickness H1 of the spacer ring 120 may be larger than 90μm, thereby preventing the cracks on the edge of the wafer 100 from propagating into the central zone A to a larger extent. In some preferrable embodiments, the predetermined thickness of the wafer 100 after being grinded may be 60μm, and the thickness H1 of the spacer ring 120 may be 80μm. Meanwhile, the thickness H1 of the spacer ring 120 may not be too large which leaves little space between a back side 100b of the wafer 100 and the spacer ring 120. This may result in a breakage of the peripheral zone B within which the deep trench 111 has been formed. Also, the thickness H1 of the spacer ring 120 may not be too small, in which case the spacer ring 120 may fail to serve as a sufficient barrier between the cracks and the central zone A. Generally, a ratio of the thickness H1 of the spacer ring 120 and the thickness H2 of the wafer 100 before being grinded may be 1/2 to 2/3. Moreover, a width W of the spacer ring 120 should be sufficient to provide enough isolation between the cracks and the central zone A. Preferably, the width W of the spacer ring 120 may be about 2mm to 10mm or even larger.

As shown in FIG. 1F, a distance D1 between the spacer ring 120 and the edge of the wafer 100 should be properly designed. To be more specific, the distance D1 refers to a distance between the edge of the wafer 100 and an edge of the spacer ring 120 which is closer to the edge of the wafer 100. On one hand, the distance D1 should be sufficient to allow for a suitable process window when forming the trench 111 within the peripheral zone B. If the distance D1 is too small, the formation of the trench 111 may lead to rupture of the wafer 100 and newly generated cracks due to the mechanical weakness of the edge of the wafer 100. On the other hand, if the distance D1 is too large, the cracks generated on the edge of the wafer 100 may grow into larger crevices, which may be difficult to be blocked by the spacer ring 120. Preferably, the distance D1 may be 1mm to 1.5mm.

Moreover, a distance D2 between the spacer ring 120 and the edge of the central zone A should also be properly designed. On one hand, the spacer ring 120 should not be far away from the central zone A so that the spacer ring 120 can provide sufficient protection for the semiconductor units within the central zone A. On the other hand, the spacer ring 120 should not be too close to the central zone A so that it may avoid potential damage to the central zone A during the formation of the trench 111. Preferably, the distance D2 may be 1 mm to 3 mm. To be more specific, the distance D2 refers to a distance between an edge of the central zone A of the wafer 100 and the edge of the spacer ring 120 which is closer to the central zone A.

As shown in FIGS. 1E and 1F, one spacer ring 120 may be formed within the peripheral zone B. In some other embodiments, more than one spacer ring 120 may be formed within the peripheral zone B. The spacer rings 120 may have decreasing diameters to form concentric rings, which may provide improved isolation to block the cracks from entering the central zone A. In some other embodiments, an additional spacer ring may be formed on the back side 100b of the wafer 100 to provide additional blocking of cracks formed at the back side 100b of the peripheral zone B from entering the central zone A. In some embodiments, the backside spacer ring may be aligned with the frontside spacer ring 120, with a gap formed therebetween. But in some other embodiments, the backside spacer ring may be offset from the frontside spacer ring 120 and not be connected with each other. Preferably, a total of a thickness of the backside spacer ring and a thickness of the frontside spacer ring 120 may be greater than that of the wafer 100.

Next, a grinding process is conducted to the wafer 100 such that a thickness of the wafer 100 can be reduced to a predetermined thickness.

As shown in FIG. 1G, the wafer 100 is attached onto a grinding platform 131 at the front side 100a of the wafer 100 with a grinding tape 132. The back side 100b of the wafer 100 is facing upward. The grinding tape 132 may be an UV sensitive tape, which may be similar to the trenching tape mentioned above. The grinding tape 132 may be adhesive after being applied onto the front side 100a of the wafer 100. The grinding tape 132 covers the front side 100a of the wafer 100, the solder bumps 101 and the spacer ring 120. The grinding tape 132 also fixes the wafer 100 onto the grinding platform 131 for a subsequent grinding process. The grinding tape 132 may prevent the wafer 100 from surface damage during the grinding process and protect the front side 100a of the wafer 100 from contamination caused by infiltration of a grinding fluid and/or debris.

In some embodiments, a portion of the grinding platform 131 which is aligned with the front side 100a of the wafer 100 may be porous. The porous portion may be fluidly connected with a vacuum pump to apply a vacuum pressure onto the grinding tape 132 and the wafer 100. Thus, the wafer 100 may be firmly adhered and secured onto the grinding platform 131.

Next, the back side 100b of the wafer 100 is grinded by a grinding device 130. The grinding device 130 may include a grinding head which is in contact with the back side 100b of the wafer 100 and conducts the grinding of the wafer 100. During the grinding process, a grinding fluid may be applied to the back side 100b of the wafer 100 to improve lubrication between the wafer 100 and the grinding head, thereby facilitating the grinding of the wafer 100. The wafer 100 may also be washed with deionized water throughout the grinding process, which helps prevent surface contamination.

As shown in FIG. 1G, the grinding device 130 may start the grinding process by grinding the edge of the wafer 100, and then the grinding device 130 goes through the peripheral zone B to the central zone A and finally walk across all the back side 100b of the wafer 100. When the grinding device 130 is in contact with the edge of the wafer 100 and starts the grinding process, the edge of the wafer 100 or the peripheral zone B may suffer from an external stress. The external stress may result in generation of the cracks on the edge of the wafer 100 or within the peripheral zone B due to a smaller thickness and larger exposure to the external stress. Here in this embodiment, the spacer ring 120 serves as a barrier to block the cracks from propagating into the central zone A of the wafer 100 to protect the semiconductor units within the central zone A. In addition, with the embedded spacer ring 120, the peripheral zone B may have an improved endurance or impact resistance when exposed to the external stress, thereby resulting in a reduced risk of generating further cracks.

In some embodiments, a portion of the wafer 100 between the back side 100b and the spacer ring 120 may be removed and the spacer ring 120 is exposed from the back side 100b of the wafer 100. Preferably, a distance H3 between a bottom surface of the spacer ring 120 and the back side 100b of the wafer 100 before the grinding of the wafer 100 may be 1/2 to 1/3 of the thickness of the wafer 100.

Next, the wafer 100 is continuously grinded by the grinding device 130. The grinding device 130 may conduct the grinding process to both of the spacer ring 120 and the wafer 100. As shown in FIG. 1H, when the grinding device 130 is in direct contact with the back side 100b of the peripheral zone B, at least a portion of the grinding head may be in direct contact with the spacer ring 120. In this way, the spacer ring 120 provides an additional mechanical support to withstand or buffer the stress applied by the grinding device, which reduces the stress applied to the rest of the peripheral zone B of the wafer 100. As such, the cracks generated on the edge of the wafer 100 or within the peripheral zone B may be further reduced. The grinding process of the wafer 100 and the spacer ring 120 may continue until a portion of the spacer ring 120 and the wafer 100 are removed to achieve a predetermined thickness of the wafer 100. In some embodiments, the predetermined thickness may be 50μm to 70μm.

In some other embodiments, the spacer ring 120 may serve as a stop layer which helps to indicate an endpoint of the grinding process. When the spacer ring 120 is exposed from the back side 100b of the wafer 100 during the grinding process, a sensor disposed on the grinding head of the grinding device 130 may detect the existence of the spacer ring 120 based on a difference in material between the spacer ring 120 and the wafer 100. The sensor may transmit a grinding-stop signal accordingly. Then the grinding device 130 may stop the grinding process based on the grinding-stop signal without further grinding of the spacer ring 120 and the wafer 100.

In some alternative embodiments, the cracks generated at the back side 100b of the peripheral zone B may propagate into the central zone A in various directions. For example, some of the cracks may propagate into the central zone A through an interspace between the back side 100b of the peripheral zone B and the spacer ring 120, thereby escaping from the blockage of the spacer ring 120 which is closest to the edge of the wafer 100. To solve this issue, more than one spacer ring 120 may be formed within the peripheral zone B in a form of concentric rings, which may provide stronger and more complete isolation to block the cracks from entering the central zone A. The spacer rings 120 may have a same width and a same thickness. It can also be appreciated that the width of the spacer rings 120 may gradually decrease with a distance between the respective spacer ring 120 and the edge of the wafer 100, thereby providing stronger blockage of the cracks at a region closer to the edge of the wafer 100. Moreover, the thickness of the spacer rings 120 may gradually increase when the respective spacer ring 120 gets closer to the central zone A to provide stronger protection for a region closer to the semiconductor units. In some embodiments, to avoid too much occupation of the wafer, two or three concentric spacer rings are preferred.

In some other embodiments, the thickness of the spacer rings may gradually increase when the respective spacer ring 120 gets closer to the edge of the wafer 100. The spacer ring 120 being the closest to the edge of the wafer 100 may have the largest thickness, which is referred to as a first spacer ring. A first grinding stage may be conducted, after which the first spacer ring may be exposed from the back side 100b while other spacer rings 120 with smaller thickness may still be embedded within the peripheral zone B and not exposed from the back side 100b of the wafer 100. At this time, both of the bottom surface and the top surface of the first spacer ring are exposed from the back side 100b and the front side 100a of the wafer 100, respectively. In this case, the first spacer ring may be removed from the rest of the wafer 100. Thereby, a first portion of the wafer 100 which is from the edge of the wafer 100 to the first spacer ring may be removed together with the removal of the first spacer ring. Since the first portion of the wafer 100 may be a portion closest to the edge of the wafer 100, the first portion of the wafer 100 may be the most vulnerable to the external stress and may suffer from the cracks the most. Thus, after the removal of the first portion of the wafer 100 and the first spacer ring, the rest of the wafer 100 may have relatively fewer cracks, which reduces cracks generated on the wafer 100 in a second grinding stage to be conducted subsequently. Similarly, during a second grinding stage, a second spacer ring which has the second largest thickness and a second portion of the wafer 100 out of the second spacer ring can be removed after the second spacer ring is exposed from the back side 100b of the wafer 100. A similar process may be repeated during the whole grinding process until the predetermined thickness of the wafer 100 is achieved, thereby reducing the overall cracks generated on the wafer 100. In some other embodiments, an additional semiconductor fabrication process may be carried out between two successive grinding stages, for example, between the first grinding stage and the second grinding stage. In this case, the cracks generated on the edge of the wafer 100 during the additional semiconductor fabrication process may also be cleared with the removal of the second spacer ring and the second portion of the wafer 100.

After achieving the predetermined thickness of the wafer 100, the grinding process is finished. Next, the UV sensitive grinding tape 132 may be hardened after UV irradiation with a certain wavelength range. In this way, an adherence of the grinding tape 132 is reduced and the grinding tape 132 can be easily removed such that the wafer 100 is separated from the grinding platform 131, as illustrated in FIG. 1I.

Afterwards, the wafer 100 may be singulated into a plurality of dice by a sawing process. The spacer ring 120 and the peripheral zone B may be removed during the sawing process.

In some embodiments, the method for grinding a wafer 100 can be used in grinding a wafer 100 with a small thickness, such as a thickness smaller than 100μm. The method may greatly reduce wafer damage and improve yield, which enhances production efficiency of semiconductor package devices.

While the exemplary method for grinding a wafer of the present application is described in conjunction with corresponding figures, it will be understood by those skilled in the art that modifications and adaptations to the method for grinding a wafer may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for grinding a wafer, the method comprising:
providing a wafer having a back side and a front side opposite to the back side, wherein the wafer further comprises a central zone for accommodating semiconductor units and a peripheral zone surrounding the central zone;
forming a trench within the peripheral zone and extending along substantially an entire circumference of the peripheral zone, wherein the trench is exposed from the front side of the wafer;
filling the trench with a filler to form a spacer ring within the peripheral zone, wherein the spacer ring isolates the central zone from an edge of the wafer;
attaching the wafer onto a platform at the front side of the wafer; and
grinding the wafer from the back side of the wafer.

2. The method of claim 1, wherein grinding the wafer from the back side of the wafer further comprises:
grinding the wafer from the back side of the wafer until a predetermined thickness of the wafer is achieved.

3. The method of claim 2, wherein the predetermined thickness is 50μm to 70μm.

4. The method of claim 2, wherein grinding the wafer from the back side of the wafer further comprises:
grinding the wafer from the back side of the wafer at least until the spacer ring is exposed from the back side of the wafer.

5. The method of claim 4, wherein grinding the wafer from the back side of the wafer further comprises: grinding the wafer from the back side of the wafer until a portion of the spacer ring is removed.

6. The method of claim 1, wherein the trench is 1mm to 1.5mm away from the edge of the wafer.

7. The method of claim 1, wherein a ratio of a thickness of the spacer ring and a thickness of the wafer is between 1/2 and 2/3.

8. The method of claim 1, wherein the spacer ring is 1mm to 3mm away from the central zone.

9. The method of claim 1, wherein the filler comprises epoxy.

10. The method of claim 1, wherein attaching the wafer onto a platform at the front side of the wafer comprises:
attaching the wafer onto the platform via an adhesive material; and
wherein after the grinding of the wafer, the method further comprises:
removing the adhesive material to separate the wafer from the platform.
